(19) United States
(12) Patent Application Publication
(10) Pub. No.: US 2010/0287732 A1
(43) Pub. Date: Nov. 18, 2010

(54) Electrical device

(75) Inventors: Yu-Hsiang Fang, Tianjhong Township (TW); Chun-Feng Lai, Sanchong City (TW); Ching-Cheng Wang, Dasi Township (TW); Jung-Wen Chang, Lujhu Township (TW)

Correspondence Address: RABIN & Berdo, PC, 1101 14TH STREET, NW, SUITE 500, WASHINGTON, DC, 20005, US

(73) Assignee: Quanta Computer Inc., Taoyuan Shien (TW)

(21) Appl. No.: 12/585,950

(22) Filed: Sep. 29, 2009

(30) Foreign Application Priority Data
May 18, 2009 (TW) 098208612

(51) Int. Cl. E05D 11/00; E05D 5/10

(52) U.S. Cl. 16/250

(57) ABSTRACT

An electrical device is provided in this invention, includes a main part having a pivot-receiving opening, an operation part having a pivot engaged pivotally to the pivot-receiving opening, and a flexible circular ring encircling the pivot, and being disposed and pressed between the pivot and the pivot-receiving opening.

### RELATED APPLICATIONS

This application claims priority to Taiwan Application Serial Number 98208612, filed May 18, 2009, which is herein incorporated by reference.

### BACKGROUND

1. Field of Invention

The present invention relates to an electrical device, more particularly to an electrical device having an operation part pivotally disposed thereon.

2. Description of Related Art

Nowadays, an operation part, such as a connector head or a web cam portion, of a 3C product provides angle adjusting by rotation. Therefore, the operation part can be rotated to work in a preferred angle by users. Normally, the operation part is pivotally coupled to a main shell part of the 3C product by way of tenon-and-mortise, and the operation part and the main shell part are made of metal materials. Thus, when the operation part is rotated by a preferred angle with respect to the main shell part, the operation part and the main shell part rub mutually to generate frictions and provide a resistance torque that keeps the operation part still in the preferred angle with respect to the main shell part.

However, since the operation part and the main shell part are coupled to rub mutually, after the operation part is rotated with respect to the main shell part in many times, the operation part and the main shell part will be tired and damaged due to characteristics of metal. Thus, the operation part and the main shell part may lose their functions quickly. Therefore, a usage life of the metal pivot becomes shorter, and the operation part cannot be rotated to any angle anymore with respect to the main shell part.

Furthermore, because the operation part is pivotally coupled to the main shell part by way of tenon-and-mortise, the resistance torque provided between the operation part and the main shell part is constant and unable to be adjusted flexibly according to user's needs whenever the operation part is pivotally coupled to the main shell part. Consequently, when the operation part pivotally coupled to the main shell part fails to provide an expected resistance torque, the operation part and the main shell part might be abandoned because they could not rework, such that high failure rate and high producing cost are further incurred.

### SUMMARY

It is therefore an aspect of the present invention to provide an electrical device.

The electrical device includes a main part, an operation part and a flexible circular ring. The main part has at least a pivot-receiving opening. The operation part has at least a pivot engaged pivotally to the pivot-receiving opening. The flexible circular ring encircles the pivot, and is arranged between the pivot and the pivot-receiving opening. Also, the flexible circular ring is pressed by the pivot and the pivot-receiving opening at the same time.

Therefore, when the operation part is rotated with respect to the main part, a torque force is provided by pressing the flexible circular ring to keep the operation part still in a position with respect to the main part.

Thus, comparing to the prior art that joining the pivot and the main shell part by way of tenon-and-mortise, the invention avoids the operation part and the main part rub against each other directly and further extends their usage live as well.

According to an embodiment of the invention, the main part has a first case body. The first case body has two pivot-receiving openings facing each other. The operation part has a second case body. The second case body has two opposite pivots respectively engaged pivotally to the pivot-receiving openings, so that the second case body rotates with respect to the first case body by the pivots. Each pivot is encircled by a flexible circular ring, and the flexible circular ring is disposed between the pivot and the pivot-receiving opening, and is pressed by the pivot and the pivot-receiving opening to provide a torque force thereto. Furthermore, when the flexible circular ring is pressed by the pivot and the pivot-receiving opening, a first pressing portion of the flexible circular ring that is pressed by the pivot-receiving opening is larger than a second pressing portion of the flexible circular ring that is pressed by the pivot.

According to an embodiment of the invention, the main part comprises a material of plastic or metal.

According to an embodiment of the invention, the flexible circular ring comprises a material of plastic, rubber, silica gel or latex.

According to an embodiment of the invention, the pivot-receiving opening has a circular shape.

According to an embodiment of the invention, the pivot-receiving opening has a polygonal shape.

The present invention also provides an electrical device capable of altering a size of the pivot-receiving opening for offering an uniform and stable torque force distribution accommodating to a user's requirement.

When the user obtains information of an outer diameter of the flexible circular ring, and a determined pre-compression amount for the flexible circular ring according to a required torque performance, the embodiment of the invention provides a rule to determine the size of the pivot-receiving opening corresponding to the above information:

1. A linear distance of the plane between the two ramps is 1.5 mm shorter than the outer diameter of the flexible circular ring.

2. A linear distance between an end point of one of the ramps and an end point of another of the ramps is 0.95 mm longer than the outer diameter of the flexible circular ring.

3. A vertical distance of the trapezoid shape plus a determined pre-compression amount of the flexible circular ring is equal to half of the outer diameter of the flexible circular ring.

Therefore, according to the mentioned rule, the invention is able to accommodate user's requirements to provide an uniform and stable torque force distribution and further to lower the failure rate and cost of production.

It is to be understood that both the foregoing general description and the following detailed description are examples, and are intended to provide further explanation of the invention as claimed.

### BRIEF DESCRIPTION OF THE DRAWINGS

These and other features, aspects and advantages of the present invention will become better understood with regard to the following description, appended claims and accompanying drawings where:

FIG. 1 is a partially exploded view of an electrical device according to an embodiment of the invention.

FIG. 2 is a cross-section view of the electrical device along a line 2-2 of FIG. 1 after the main part and the operation part are assembled together.

FIG. 3 is a fully exploded view of the electrical device according to an embodiment of the invention.

FIG. 4A is a front view of a circular shaped pivot-receiving opening of the electrical device according to an embodiment of the invention.

FIG. 4B is a front view of an octagonal shaped pivot-receiving opening of the electrical device according to an embodiment of the invention.

FIG. 5 is a front view of a hexagonal shaped pivot-receiving opening of the electrical device according to an embodiment of the invention.

FIG. 6 is a torque force distribution chart of a flexible circular ring rotated with an unstable torque force.

FIG. 7 is another torque force distribution chart of a flexible circular ring of the electrical device rotated with a stable torque force according to an embodiment of the invention.

FIG. 8 is a table regarding relationship between gaps, pre-compression amounts and torque force.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

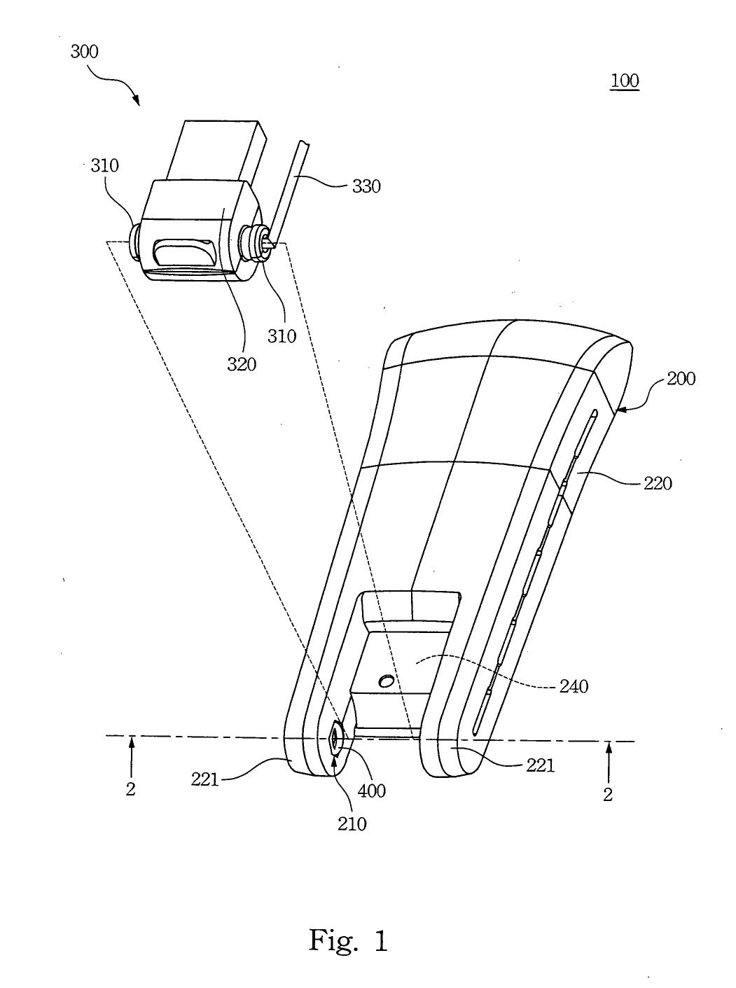

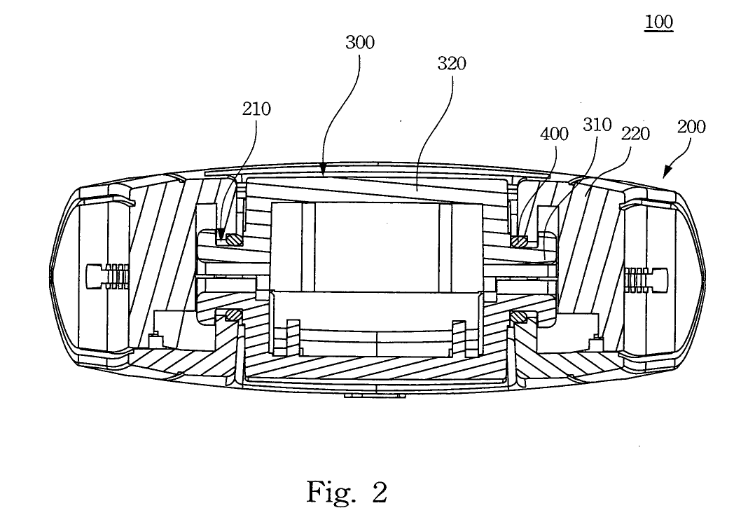

Refer to FIG. 1 and FIG. 2. FIG. 1 is a partially exploded view of an electrical device according to an embodiment of the invention. FIG. 2 is a cross-section view of the electrical device along a line 2-2 of FIG. 1 after the main part and the operation part are assembled together. An electrical device 100 comprises a main part 200, an operation part 300 and a flexible circular ring 400. The main part 200 has at least one pivot-receiving opening 210. The operation part 300, via a pivot 310, is engaged pivotally to the pivot-receiving opening 210. The flexible circular ring 400 encircles the pivot 310, and is arranged between the pivot 310 and the pivot-receiving opening 210.

Therefore, when the operation part 300 is rotated with respect to the main part 200, a torque force is provided by pressing the flexible circular ring 400 to keep the operation part 300 still in a position with respect to the main part 200.

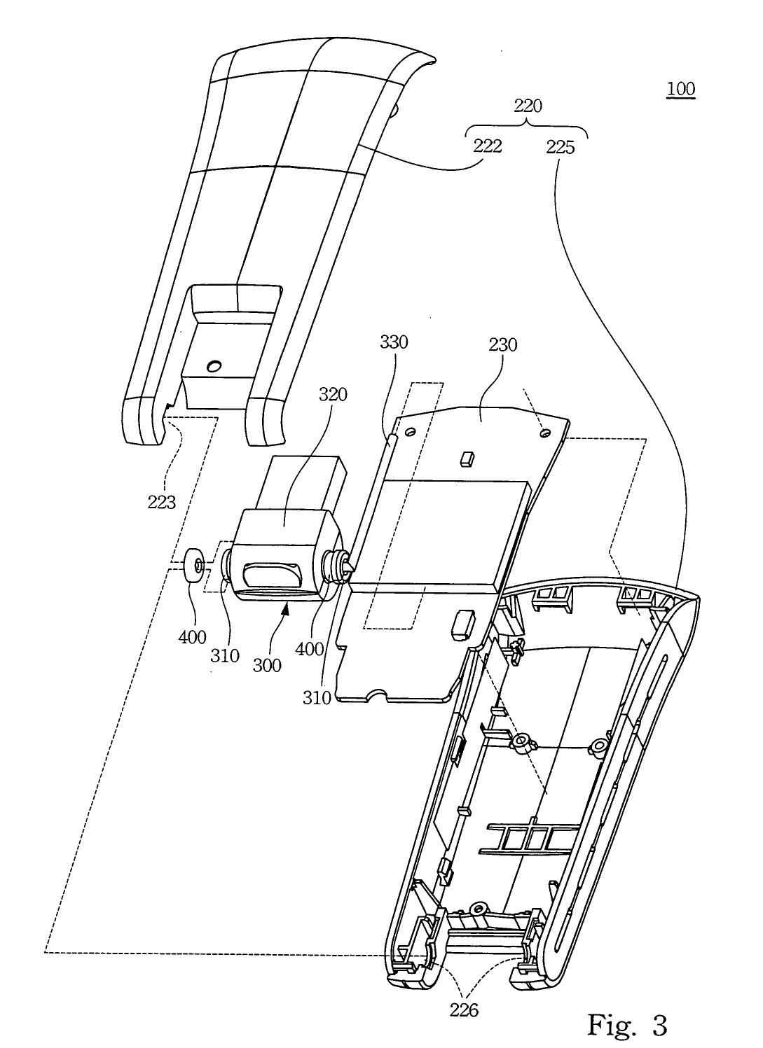

Refer to FIG. 3. FIG. 3 is a fully exploded view of the electrical device according to an embodiment of the invention. The main part 200 has a first case body 220 and a first circuit module 230. The first case body 220 has two flanges 221 and an opening space 240. The two flanges 221 extend along a same direction at one end of the first case body 220, and the opening space 240 is formed therebetween. Each flange 221 is provided one pivot-receiving opening 210 at one side thereof, and the two pivot-receiving openings 210 are facing each other.

The operation part 300 has a second case body 320 and a second circuit module (not shown) therein. The second circuit module is electrically connected with the first circuit module 230 via a wire 330.

The second case body 320 has two pivots 310 respectively disposed at one of two opposite sides of the second case body 320, and each pivot 310 is corresponding to one of the pivot-receiving openings 210 of the first case body 220. After the pivots 310 are respectively encircled by the flexible circular rings 400, and engaged pivotally to the pivot-receiving opening 210, the second case body 320 could be rotated into or out of the opening space 240 along the pivot 310 as a rotation axle.

In details, the first case body 220 can be assembled by an upper case 222 and a lower case 225. The upper case 222 has an upper indentation 223, and the lower case 225 has a lower indentation 226 aligning to the upper indentation 223 for forming the pivot-receiving opening 210 on the first case body 220 after combining the upper indentation 223 and the lower indentation 226.

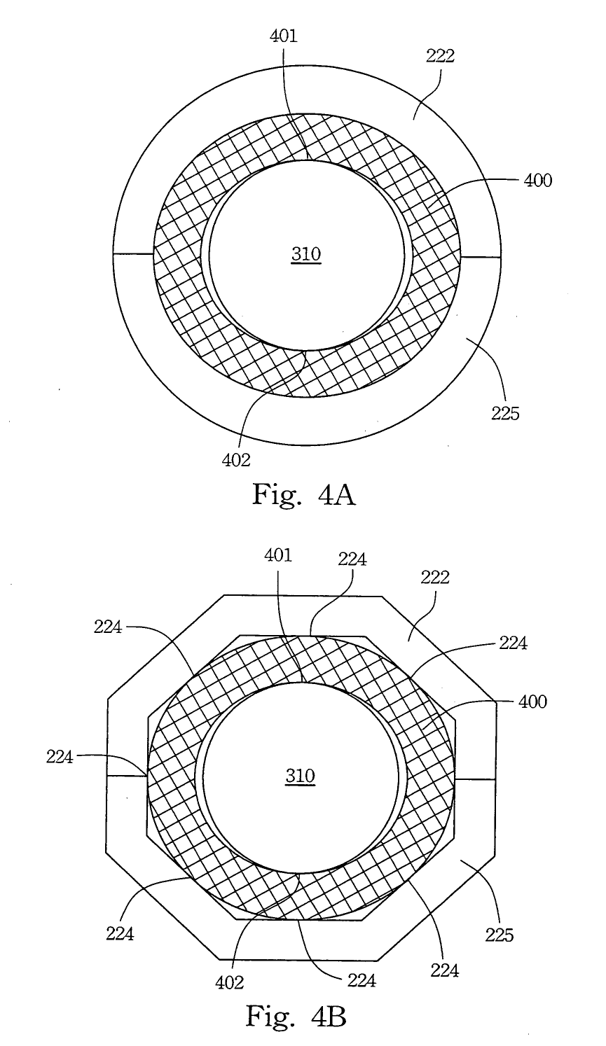

Meanwhile, when the flexible circular rings 400 is pressed between the pivot-receiving opening 210 and the pivot 310, two pressing portions 401, 402 of an inner surface of the flexible circular ring 400 contact an outer surface of the pivot 310 (see FIG. 4A and FIG. 4B).

According to the embodiment, the first case body 220 at least comprises material of plastic or metal (e.g. aluminum, iron etc.), but is not limited to those. The second case body 320 at least comprises material of plastic or metal (e.g. aluminum, iron etc.), but is not limited to those. The flexible circular ring 400 comprises material of plastic, rubber, silica gel or latex, but is not limited to those.

The appearance (e.g. shape) of the pivot-receiving opening 210 also influences the rotation condition of which the operation part 300 is rotated with respect to the main part 200, and the torque force distribution provided from the operation part 300 and the pivot-receiving opening 210 pressing the flexible circular ring 400. For instance, the pivot-receiving opening 210 can be designed to have a circular shape (as shown in FIG. 4A) or a polygonal shape, such as hexagonal shape (as shown in FIG. 1) or octagonal shape (as shown in FIG. 4B).

If the pivot-receiving opening 210 appears as a circular shape, inner surface of the pivot-receiving opening 210 fully contact outer surface of the flexible circular rings 400 to press the flexible circular rings 400. If the pivot-receiving opening 210 appears as a polygonal shape, each side of the polygonal shaped pivot-receiving opening 210 respectively contacts to press the outer surface of is the flexible circular rings 400 with a pressing portion 224. On the other hand, the two opposite pressing portions 401, 402 of the inner surface of the flexible circular ring 400 are respectively pressed by the pivot 310.

Since the contact area between the pivot-receiving opening 210 and the flexible circular rings 400 is larger than that between the pivot 310 and the flexible circular rings 400, frictions between the flexible circular ring 400 and the pivot-receiving opening 210 will be greater than frictions between the flexible circular ring 400 and pivot 310. Therefore, once the operation part 300 is rotated with respect to the main part 200, the flexible circular ring 400 avoids the pivot 310 and pivot-receiving opening 210 (i.e. main part 200) from rubbing directly with each other, thus extends the pivot 310 and pivot-receiving opening 210's usage live without sacrificing normal rotation function. Furthermore, the flexible circular ring 400 also helps to provide an effective, stable and uniform torque force when the pivot 310 is rotated with respect to the pivot-receiving opening 210.

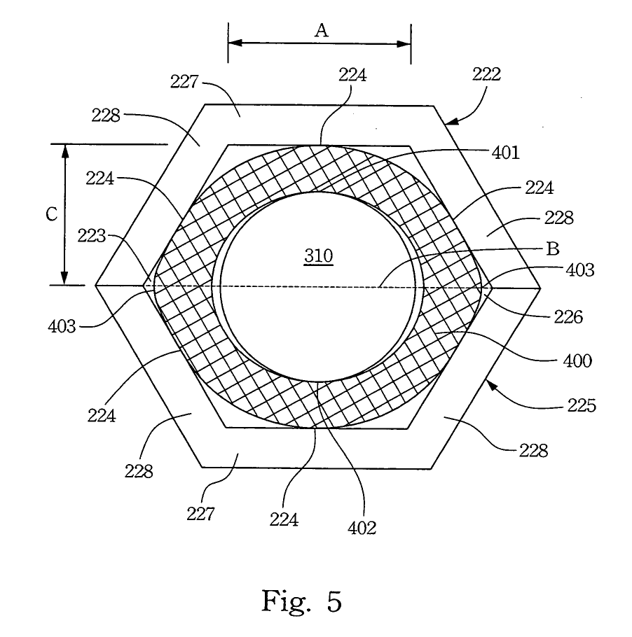

Refer to FIG. 5. FIG. 5 is a front view of a hexagonal shaped pivot-receiving opening of the electrical device according to an embodiment of the invention. In the embodiment of the invention, the pivot-receiving opening 210 has a hexagonal shape, and both the upper indentation 223 and the lower indentation 226 have a trapezoid shape for forming the hexagonal shaped pivot-receiving opening 210 when the upper case 222 and the lower case 225 are assembled together. The trapezoid shape is defined by a plane 227 and two ramps 228 of the upper indentation 223 and the lower indentation 226. The plane 227 is placed between the two ramps 228, and each ramp 228 extends outwardly from one of the opposite edges of the plane 227.

Furthermore, since the torque force provided from the conventional art is constant and fails to be adjusted flexibly according to user's needs, the invention provide an electrical device capable of altering the size of the pivot-receiving opening 210 of the main part 200 for offering an uniform and stable torque force distribution to accommodate user's requirements. Therefore, the embodiment of the electrical device provides a better rotation quality.

Following the above embodiment in which the pivot-receiving opening 210 is hexagonal-shaped, and the flexible circular ring 400 comprises is rubber material. Once the user obtains information of an outer diameter of the flexible circular ring 400 and pre-compression amount for each side (i.e. pressing portion 224) of the flexible circular ring 400 by the upper case 222 and lower case 225, a rule to determine the size of the upper indentation 223 or the lower indentation 226 corresponding to the above values is provided as followings:

Reference “A”=the outer diameter of the flexible circular ring 400—1.5 mm.

Reference “A” represents a linear distance of the plane 227 between the two ramps 228 (i.e. shorter edge of two parallel edges in the trapezoid shape of the upper indentation 223 or lower indentation 226).

Reference “B”=the outer diameter of the flexible circular ring 400+0.95 mm.

Reference “B” represents a linear distance between the two ramps 228 from an end point of one ramp 228 to an end point of another ramp 228 (i.e. longer edge of the two parallel edges in the trapezoid shape of the upper indentation 223 or lower indentation 226).

Reference “C”=half of the outer diameter of the flexible circular ring 400—the pre-compression amount.

Reference “C” represents a height or vertical distance of the trapezoid shape from the plane 227 to a line defined by the end points of the two ramps.

The pre-compression amount can be defined as a deformed range (or distance in the unit mm) at each side (i.e. pressing portion 224) of the flexible circular ring 400 pressed by the upper indentation 223 and lower indentation 226.

Therefore, by the mentioned rule, when the upper case 222 and the lower case 225 are assembled with each other, and respectively press the flexible circular ring 400 by the upper indentation 223 and the lower indentation 226, a position of the flexible circular ring 400 near the interface between the upper indentation 223 and the lower indentation 226 (i.e. deformed positions 403) of the flexible circular ring 400 will not to be clipped or deformed by the upper case 222 and the lower case 225 while that is an apparent drawback in the conventional art.

Furthermore, gaps between the pivot 310 and the flexible circular ring 400 before the flexible circular ring 400 being pressed might also influence the torque force distribution of the flexible circular ring 400.

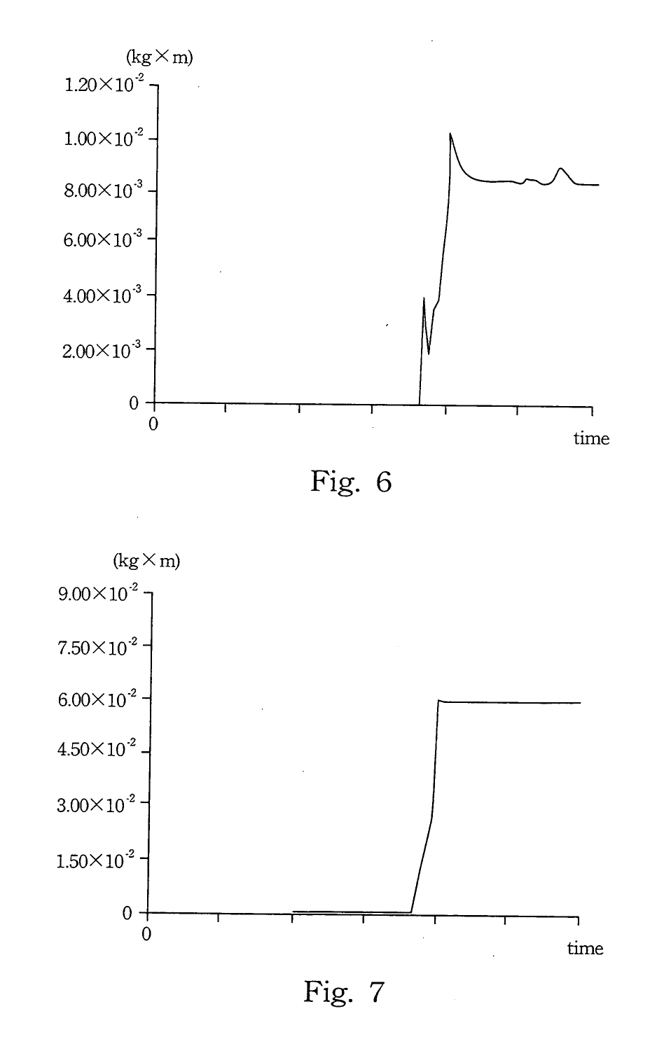

Refer to FIG. 6. FIG. 6 shows a torque force distribution chart of a flexible circular ring rotated with an unstable torque force. If the pre-compression amount for each side of the circular ring 400 is shorter than gap, before being pressed, between a pivot 310 and the circular ring 400, the circular ring 400 will be twisted to deform itself and slid to move laterally when the circular ring 400 is pressed by an upper case 222 and a lower case 225 (as mentioned previously). Thus, when an operation part 300 is rotated with respect to a main part 200, the circular ring 400 will provide an unstable torque force during the rotation process.

Refer to FIG. 7 and FIG. 5. FIG. 7 shows another torque force distribution chart of a flexible circular ring of the electrical device rotated with a stable torque force according to an embodiment of the invention. If the pre-compression amount for the flexible circular ring 400 is longer or larger than the gap, before being pressed, between the pivot 310 and the flexible circular ring 400, for example, the pre-compression amount mentioned above is assumed as 0.35 mm, and the gap mentioned above is assumed as 0.1 mm, thus the problem of the flexible circular ring 400 being deformed and slid to move laterally will be overcome. Therefore, once the operation part 300 is rotated with respect to the main part 200, the flexible circular ring 400 provides a stable torque force during the rotation process.

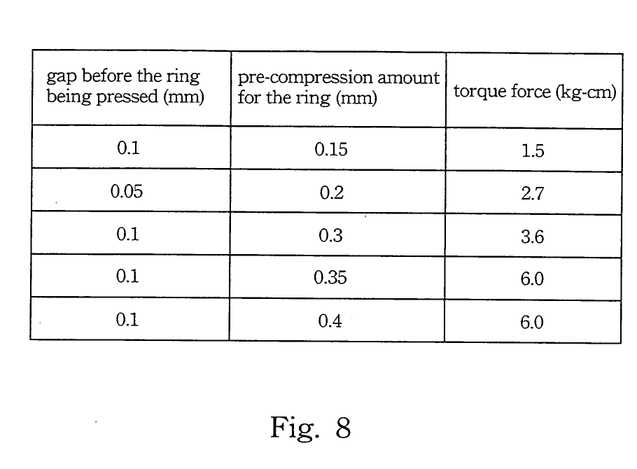

Refer to FIG. 8. FIG. 8 shows a table regarding relationship between gaps, pre-compression amounts and torque force. The torque force for the operation part 300 can be influenced by altering the pre-compression amounts for each side of the flexible circular ring 400. When the pre-compression amount for the flexible circular ring 400 is longer or larger, the torque force is greater. In this embodiment, the pre-compression amount for the flexible circular ring 400 is suggested in a range from 0.15 mm to 0.4 mm.

The torque force also varies depending on the material(s) of the flexible circular ring 400. For example of a rubber flexible circular ring 400, with gaps between the pivot 310 and the flexible circular ring 400 before being pressed is sized in a range from 0.05 mm to 0.1 mm, and the pre-compression amount is sized in a range from 0.15 mm to 0.4 mm, a torque force can be obtained from a is range from 1.5 kg-cm to 6.0 kg-cm when the operation part 300 is rotated with respect to the main part 200.

In this specification, the electrical device 100 mentioned above can be exampled as a Personal Digital Assistant (PDA), an electronic dictionary device, a notebook, a mobile phone or other hand-held electrical product, and the operation part 300 can be exampled as a connector (e.g. USB type connector), an antenna portion (e.g. antenna for Wimax product of or digital TV), a camera portion (e.g. WEB Cam) or the like, and the main part 200 is widely meant that the element cannot be rotated with the operation part 300 at the same time.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electrical device, comprising:
a main part having a pivot-receiving opening;
an operation part having a pivot engaged pivotally to the pivot-receiving opening; and
a flexible circular ring encircling the pivot, and being disposed and pressed between the pivot and the pivot-receiving opening.

2. The electrical device of claim 1, wherein the pivot-receiving opening has a hexagonal shape.

3. The electrical device of claim 1, wherein the main part comprises:
an upper case having an upper indentation; and
a lower case having a lower indentation,
wherein the upper indentation and the lower indentation are combined to form the pivot-receiving opening.

4. The electrical device of claim 3, wherein the pivot-receiving opening has a polygonal shape having plural sides thereof, and each side of the pivot-receiving opening respectively presses a first pressing portion of an outer surface of the flexible circular ring.

5. The electrical device of claim 4, wherein the pivot-receiving opening has a hexagonal shape.

6. The electrical device of claim 1, wherein the upper indentation and the lower indentation respectively has a trapezoid shape with two ramps and a plane disposed between the ramps.

7. The electrical device of claim 6, wherein a linear distance of the plane between the ramps is 1.5 mm shorter than an outer diameter of the flexible circular ring;
a linear distance between an end point of one of the ramps to an end point of another of the ramps is 0.95 mm longer than the outer diameter of the flexible circular ring; and
a vertical distance of the trapezoid shape plus a determined pre-compression amount of the flexible circular ring is equal to half of the outer diameter of the flexible circular ring.

8. The electrical device of claim 7, wherein two opposite second pressing portions of an inner surface of the flexible circular ring are respectively pressed by the pivot.

9. The electrical device of claim 1, wherein the flexible circular ring comprises a material of plastic, rubber, silica gel or latex.

10. The electrical device of claim 4, wherein the pivot-receiving opening has an octagonal shape.

11. The electrical device of claim 3, wherein the pivot-receiving opening has a circular shape, and an inner surface of the pivot-receiving opening presses an outer surface of the flexible circular ring.

12. An electrical device, comprising:
a first case body having two pivot-receiving openings facing each other, and each of the pivot-receiving openings having a hexagonal shape, respectively;
a second case body having two opposite pivots respectively engaged pivotally to the pivot-receiving openings, so that the second case body rotates relative to the first case body by the pivots; and
two flexible circular rings, respectively encircling one of the pivots, and being disposed and pressed between the pivot and one of the pivot-receiving openings,
wherein a first pressing portion that the flexible circular ring is pressed by the pivot-receiving opening is larger than a second pressing portion that the flexible circular ring is pressed by the pivot.

13. The electrical device of claim 12, wherein an inner surface of the flexible circular ring is pressed by the pivot on two opposite pressing portions of the flexible circular ring.

14. The electrical device of claim 12, wherein the first case body comprises:
an upper case having two upper indentations; and
a lower case having two lower indentations, and each lower indentation aligning to one of the upper indentations,
wherein when the upper case and the lower case are combined to form the pivot-receiving openings.

15. The electrical device of claim 14, wherein each of the upper indentation and the lower indentation respectively has two ramps and a plane disposed between the ramps.

16. The electrical device of claim 15, wherein a linear distance of the plane between the ramps is 1.5 mm shorter than an outer diameter of the flexible circular ring;
a linear distance between an end point of one of the ramps to an end point of is another of the ramps is 0.95 mm longer than the outer diameter of the flexible circular ring; and
a vertical distance from the plane to a line defined by the end points of the two ramps plus a determined pre-compression amount of the flexible circular ring is equal to half of the outer diameter of the flexible circular ring.

17. The electrical device of claim 16, wherein an inner surface of the flexible circular ring is pressed by the pivot on two opposite pressing portions of the flexible circular ring.

18. The electrical device of claim 17, wherein the torque force is in a range of 1.5 Kg-cm to 6.0 Kg-cm.

19. The electrical device of claim 18, wherein the flexible circular ring comprises a material of plastic, rubber, silica gel or latex.

20. The electrical device of claim 12, wherein the torque force is in a range of 1.5 Kg-cm to 6.0 Kg-cm.
